(19) United States
(12) Patent Application Publication
(10) Pub. No.: US 2022/0219526 A1
(43) Pub. Date: Jul. 14, 2022

(54) VEHICLE TEMPERATURE ADJUSTMENT SYSTEM

(71) Applicant: HONDA MOTOR CO., LTD., Tokyo (JP)

(72) Inventor: Takuya HONJO, Tokyo (JP)

(73) Assignee: HONDA MOTOR CO., LTD., Tokyo (JP)

(21) Appl. No.: 17/573,166

(22) Filed: Jan. 11, 2022

(30) Foreign Application Priority Data
Jan. 13, 2021 (JP) 2021-003818

(51) Int. Cl. B60K 11/02; B60L 58/26; B60H 1/00

(52) U.S. Cl. CPC B60K 11/02; B60L 58/26; B60H 1/00278; B60H 2001/00307; B60L 2240/545; B60L 2240/36; B60H 1/00392

(57) ABSTRACT

A vehicle temperature adjustment system includes a first temperature adjustment circuit, a second temperature adjustment circuit, and a heat exchanger. The second temperature adjustment circuit includes a first radiator configured to perform heat exchange between the second temperature adjustment medium and outside air, a first branch flow path of the second temperature adjustment medium bypassing the heat exchanger, a second branch flow path of the second temperature adjustment medium passing through the heat exchanger, and a flow rate adjustment valve configured to adjust a flow rate of the second temperature adjustment medium to the second branch flow path.

### CROSS-REFERENCE TO RELATED APPLICATIONS

This application is based on and claims priority under 35 USC 119 from Japanese Patent Application No. 2021-003818 filed on Jan. 13, 2021.

### TECHNICAL FIELD

The present disclosure relates to a vehicle temperature adjustment system mounted on an electric vehicle or the like.

### BACKGROUND ART

In related art, there has been known a vehicle including a rotary electric machine and an electric power conversion device, such as an electric vehicle. In general, since the rotary electric machine and the electric power conversion device generate heat during operation, a vehicle temperature adjustment system which adjusts a temperature of the rotary electric machine and the power conversion device is mounted on a vehicle including the rotary electric machine and the power conversion device.

For example JP-A-2001-238406 discloses a vehicle temperature adjustment system including a circulation path L through which oil circulates and which cools an electric motor M, a circulation path F through which cooling water circulates and which cools an inverter U, and a heat exchange unit (oil cooler C) which performs heat exchange between the cooling water flowing through the circulation path F and the oil flowing through the circulation path L. A radiator R is provided in the circulation path F, and the cooling water flowing through the circulation path F is cooled by the radiator R. The oil flowing through the circulation path L is cooled by the heat exchange between the cooling water flowing through the circulation path F and the oil flowing through the circulation path L in the heat exchange unit (oil cooler C). Therefore, in the vehicle temperature adjustment system in JP-A-2001-238406, a radiator for cooling the oil is not necessary, and the cooling water flowing through the circulation path F and the oil flowing through the circulation path L can be cooled by one radiator, thereby miniaturizing the vehicle temperature adjustment system.

JP-A-2019-103334 discloses a vehicle cooling device which cools oil by reducing a discharge amount of an electric water pump so that a temperature of the oil is increased when the temperature of the oil is lower than a predetermined value, and changing the discharge amount of the electric water pump in proportion to a vehicle speed so that the temperature of the oil is decreased when the temperature of the oil is equal to or higher than the predetermined value.

In order to prevent friction loss of a rotary electric machine such as an electric motor, it is desirable to keep the oil for lubricating the rotary electric machine at an appropriate temperature, but in the configuration in JP-A-2001-238406, heat exchange is always performed between the oil for cooling an electric motor M and the cooling water for cooling an inverter U. and thus there is a problem that it is difficult to adjust the temperature of the oil.

Further, in the configuration in JP-A-2019-103334, since a heat exchanger 12 and an inverter cooling circuit 10 for cooling the inverter 2 are connected in series, heat exchange always occurs between the inverter cooling circuit 10 and a T/M oil circuit 20 for cooling a first motor 3 and a second motor 4, and there is a problem that the efficiency of the first motor 3 and the second motor 4 is poor when the temperature is raised. Further, in the configuration in JP-A-2019-103334, since the cooling water is always supplied to the heat exchanger 12 at the same flow rate, there is a problem that the flow path resistance is increased and a pump having a large output is required.

### SUMMARY

The present disclosure provides a vehicle temperature adjustment system which can prevent friction loss of a rotary electric machine.

According to an aspect of the present disclosure, there is provided a vehicle temperature adjustment system, including:

a first temperature adjustment circuit which is configured to adjust a temperature of a rotary electric machine and in which a first pump is provided;

a second temperature adjustment circuit which is configured to adjust a temperature of an electric power conversion device and in which a second pump is provided; and

a heat exchanger configured to perform heat exchange between a first temperature adjustment medium circulating through the first temperature adjustment circuit and a second temperature adjustment medium circulating through the second temperature adjustment circuit, in which:

the second temperature adjustment circuit includes:
a first radiator configured to perform heat exchange between the second temperature adjustment medium and outside air;
a first branch flow path of the second temperature adjustment medium bypassing the heat exchanger;
a second branch flow path of the second temperature adjustment medium passing through the heat exchanger; and
a flow rate adjustment valve configured to adjust a flow rate of the second temperature adjustment medium to the second branch flow path.

According to the present disclosure, friction loss of a rotary electric machine can be prevented.

### BRIEF DESCRIPTION OF DRAWINGS

FIG. 1 is a block diagram illustrating a vehicle temperature adjustment system according to an embodiment of the present disclosure.

FIG. 2 is a diagram illustrating an example of control of a valve device in accordance with an increase in a required output of an electric motor.

FIG. 3 is a flowchart illustrating an example of control of a rotation speed of a second pump based on a temperature detected by each temperature sensor.

FIG. 4 is a diagram illustrating an example of a front portion of a vehicle.

FIG. 5 is a flowchart illustrating an example of control of the valve device based on a vehicle speed.

### DESCRIPTION OF EMBODIMENTS

Hereinafter, an embodiment of a vehicle in which a vehicle temperature adjustment system according to the present disclosure is mounted will be described with reference to the accompanying drawings. It should be noted that the drawings are viewed in a direction of reference numerals. In the present specification and the like, in order to simplify and clarify the description, a front-rear direction, a left-right direction, and an upper-lower direction are respectively described in accordance with directions viewed from a driver of a vehicle. In the drawings, a front side of the vehicle is denoted by Fr, a rear side thereof is denoted by Rr, a left side thereof is denoted by L, a right side thereof is denoted by R, an upper side thereof is denoted by U. and a lower side thereof is denoted by D.

### Embodiment

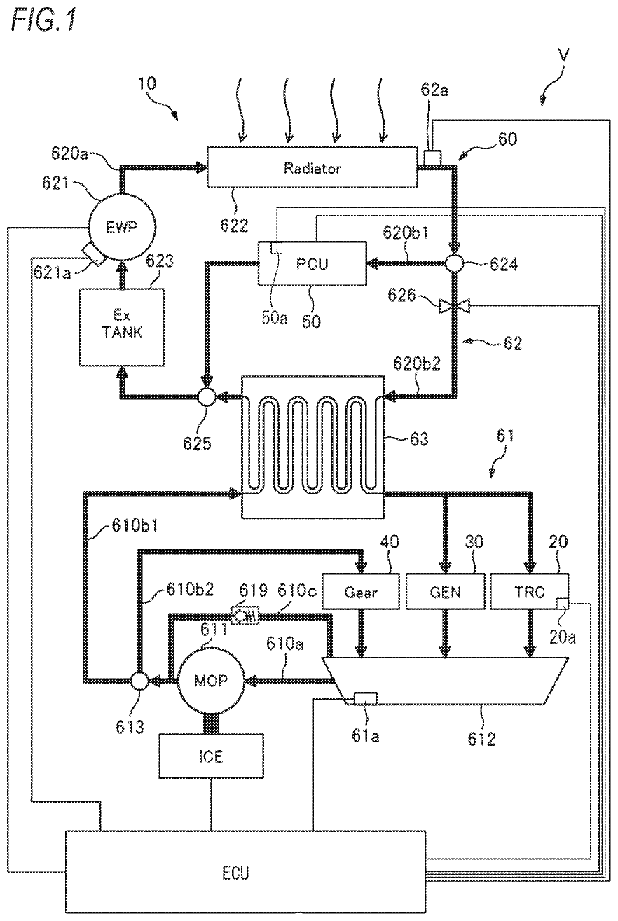

First, a vehicle temperature adjustment system 10 according to an embodiment of the present disclosure will be described with reference to FIG. 1.

As illustrated in FIG. 1, the vehicle temperature adjustment system 10 according to the present embodiment is mounted on a vehicle V, and includes an internal combustion engine ICE, a control device ECU, an electric motor 20, a power generator 30, a transmission device 40, an electric power conversion device 50, and a temperature adjustment circuit 60.

The electric motor 20 is a rotary electric machine which outputs power for driving the vehicle V using electric power stored in an electric storage device (not illustrated) mounted on the vehicle V or electric power generated by the power generator 30. When the vehicle V is braked, the electric motor 20 may generate electric power by kinetic energy of drive wheels of the vehicle V to charge the electric storage device described above. The electric motor 20 is provided with a third temperature sensor 20a which detects the temperature of the electric motor 20. The third temperature sensor 20a outputs a detection value of the temperature of the electric motor 20 to the control device ECU.

The power generator 30 is a rotary electric machine which generates electric power by the power of the internal combustion engine ICE, charges the electric storage device described above, or supplies electric power to the electric motor 20.

The transmission device 40 is a device, such as a gear-type power transmission device, reducing a speed of the power output from the electric motor 20 and transmitting the speed-reduced power to the drive wheels.

The electric power conversion device 50 includes a power drive unit (PDU) (not illustrated) which converts the electric power output from the electric storage device described above from a direct current to an alternating current to control input and output power of the electric motor 20 and the power generator 30, and a voltage control unit (VCU) (not illustrated) which boosts the electric power output from the electric storage device described above as necessary. The VCU may step down the electric power generated by the electric motor 20 when the electric motor 20 generates the electric power in a case where the vehicle V is braked. The electric power conversion device 50 is provided with a fourth temperature sensor 50a which detects the temperature of the electric power conversion device 50. The fourth temperature sensor 50a outputs a detection value of the temperature of the electric power conversion device 50 to the control device ECU.

The temperature adjustment circuit 60 includes a first temperature adjustment circuit 61 through which a non-conductive first temperature adjustment medium TCM1 circulates and which adjusts temperature of the electric motor 20, the power generator 30, and the transmission device 40; a second temperature adjustment circuit 62 through which a conductive second temperature adjustment medium TCM2 circulates and which adjusts a temperature of the electric power conversion device 50; and a heat exchanger 63 which performs heat exchange between the first temperature adjustment medium TCM1 and the second temperature adjustment medium TCM2. The non-conductive first temperature adjustment medium TCM1 is, for example, oil which is called automatic transmission fluid (ATF), can lubricate the electric motor 20, the power generator 30, and the transmission device 40, and can adjust the temperature thereof. The conductive second temperature adjustment medium TCM2 is, for example, cooling water which is called long life coolant (LLC).

The first temperature adjustment circuit 61 is provided with a first pump 611 and a storage unit 612. The first pump 611 is a mechanical pump driven by the power of the internal combustion engine ICE and a rotational force of an axle (not illustrated) of the vehicle V. The storage unit 612 stores the first temperature adjustment medium TCM1 circulating through the first temperature adjustment circuit 61. The storage unit 612 is, for example, an oil pan provided at a bottom of a housing (not illustrated) in which the electric motor 20, the power generator 30, and the transmission device 40 are housed. The first temperature adjustment circuit 61 includes a branching portion 613. The first temperature adjustment circuit 61 includes: a pressure feed flow path 610a in which the first pump 611 is provided, of which an upstream end portion is connected to the storage unit 612, and of which a downstream end portion is connected to the branching portion 613 through the first pump 611; a first branch flow path 610b1 in which the electric motor 20 and the power generator 30 are provided, of which an upstream end portion is connected to the branching portion 613, and of which a downstream end portion is connected to the storage unit 612 through the electric motor 20 and the power generator 30; and a second branch flow path 610b2 in which the transmission device 40 is provided, of which an upstream end portion is connected to the branching portion 613, and of which a downstream end portion is connected to the storage unit 612 through the transmission device 40. In the first temperature adjustment circuit 61, the heat exchanger 63 is disposed upstream of the electric motor 20 and the power generator 30 in the first branch flow path 610b1.

Therefore, in the first temperature adjustment circuit 61, a flow path in which the first temperature adjustment medium TCM1 pressure-fed from the first pump 611 is cooled by the heat exchange with the second temperature adjustment medium TCM2 in the heat exchanger 63 through the first branch flow path 610b1 from the branching portion 613, is supplied to the electric motor 20 and the power generator 30 to lubricate the electric motor 20 and the power generator 30 and adjust the temperature thereof, and then is stored in the storage unit 612, and a flow path in which the first temperature adjustment medium TCM1 pressure-fed from the first pump 611 is supplied to the transmission device 40 through the second branch flow path 610b2 from the branching portion 613 to lubricate the transmission device 40 and adjust the temperature thereof, and then is stored in the storage unit 612 are formed in parallel. The first temperature adjustment medium TCM1 stored in the storage unit 612 flows through the pressure feed flow path 610a and is supplied to the first pump 611, and the first temperature adjustment medium TCM1 circulates through the first temperature adjustment circuit 61.

In the present embodiment, the first branch flow path 610b1 and the second branch flow path 610b2 are formed such that a flow rate of the first temperature adjustment medium TCM1 flowing through the first branch flow path 610b1 is larger than a flow rate of the first temperature adjustment medium TCM1 flowing through the second branch flow path 610b2.

The first temperature adjustment circuit 61 is provided with a first temperature sensor 61a which detects a temperature of the first temperature adjustment medium TCM1 circulating through the first temperature adjustment circuit 61. In the present embodiment, the first temperature sensor 61a is provided in the storage unit 612, which is an oil pan, and detects the temperature of the first temperature adjustment medium TCM1 stored in the storage unit 612.

The first temperature sensor 61a outputs a detection value of the temperature of the first temperature adjustment medium TCM1 stored in the storage unit 612 to the control device ECU. The first temperature adjustment circuit 61 further includes a pressure adjustment circuit 610c of which an upstream end portion is connected to the storage unit 612, and of which a downstream end portion is connected to the pressure feeding flow path 610a on a downstream side of the first pump 611. The pressure adjustment circuit 610c is provided with a pressure adjustment valve 619. The pressure adjustment valve 619 may be a check valve or an electromagnetic valve such as a solenoid valve. When the liquid pressure of the first temperature adjustment medium TCM1 pressure-fed from the first pump 611 is equal to or higher than a predetermined pressure, the pressure adjustment valve 619 is opened, and a part of the first temperature adjustment medium TCM1 pressure-fed from the first pump 611 is returned to the storage unit 612. Accordingly, the liquid pressure of the first temperature adjustment medium TCM1 flowing through the first branch flow path 610b1 and the second branch flow path 610b2 is held to be equal to or lower than the predetermined pressure.

The second temperature adjustment circuit 62 is provided with a second pump 621, a radiator 622, and a storage tank 623. The second pump 621 is, for example, an electric pump which is driven by the electric power stored in the electric storage device. The radiator 622 is disposed at a front portion of the vehicle V. and is a heat dissipation device which cools the second temperature adjustment medium TCM2 by traveling wind when the vehicle V is traveling. The storage tank 623 is a tank in which the second temperature adjustment medium TCM2 circulating through the second temperature adjustment circuit 62 is temporarily stored. Even when cavitation occurs in the second temperature adjustment medium TCM2 circulating through the second temperature adjustment circuit 62, the cavitation occurred in the second temperature adjustment medium TCM2 disappears because the second temperature adjustment medium TCM2 circulating through the second temperature adjustment circuit 62 is temporarily stored in the storage tank 623.

The second temperature adjustment circuit 62 includes a branching portion 624 and a merging portion 625. The second temperature adjustment circuit 62 includes a pressure feed flow path 620a in which the storage tank 623, the second pump 621, and the radiator 622 are provided in this order from an upstream side, of which an upstream end portion is connected to the merging portion 625, and of which a downstream end portion is connected to the branching portion 624 through the storage tank 623, the second pump 621, and the radiator 622. The second temperature adjustment medium TCM2 stored in the storage tank 623 is pressure-fed by the second pump 621 through the pressure feed flow path 620a, and is cooled by the radiator 622.

The second temperature adjustment circuit 62 further includes: a first branch flow path 620b1 in which the electric power conversion device 50 is provided, of which an upstream end portion is connected to the branching portion 624, and of which a downstream end portion is connected to the merging portion 625 through the electric power conversion device 50; and a second branch flow path 620b2 in which the heat exchanger 63 is provided, of which an upstream end portion is connected to the branching portion 624, and of which a downstream end portion is connected to the merging portion 625 through the heat exchanger 63. In the present embodiment, a valve device 626 is provided as a flow rate adjustment valve in a portion of the second branch flow path 620b2 upstream of the heat exchanger 63. In the present embodiment, the valve device 626 may be an ON-OFF valve which switches the second branch flow path 620b2 between a fully open state and a fully closed state, or may be a variable flow rate valve which can adjust a flow rate of the second temperature adjustment medium TCM2 flowing through the second branch flow path 620b2. The valve device 626 is controlled by the control device ECU.

Therefore, the second temperature adjustment medium TCM2 pressure-fed by the second pump 621 and cooled by the radiator 622 in the pressure-feed flow path 620a branches into the first branch flow path 620b1 and the second branch flow path 620b2 at the branching portion 624. The second temperature adjustment medium TCM2 flowing through the first branch flow path 620b1 cools the electric power conversion device 50 and is merged with the second branch flow path 620b2 and the pressure feeding flow path 620a at the merging portion 625. The second temperature adjustment medium TCM2 flowing through the second branch flow path 620b2 cools the first temperature adjustment medium TCM1 by exchanging heat with the first temperature adjustment medium TCM1 in the heat exchanger 63, and is merged with the first branch flow path 620b1 and the pressure feed flow path 620a at the merging portion 625. The second temperature adjustment medium TCM2 flowing through the first branch flow path 620b1 and the second temperature adjustment medium TCM2 flowing through the second branch flow path 620b2 are merged at the merging portion 625, flow through the pressure feed flow path 620a, and are temporarily stored in the storage tank 623. Then, the second temperature adjustment medium TCM2 stored in the storage tank 623 is supplied again to the second pump 621 through the pressure feed flow path 620a, and the second temperature adjustment medium TCM2 circulates through the second temperature adjustment circuit 62.

In the present embodiment, the first branch flow path 620b1 and the second branch flow path 620b2 are formed such that the flow rate of the second temperature adjustment medium TCM2 flowing through the first branch flow path 620b1 is larger than the flow rate of the second temperature adjustment medium TCM2 flowing through the second branch flow path 620b2.

The second temperature adjustment circuit 62 is provided with a second temperature sensor 62a which detects a temperature of the second temperature adjustment medium TCM2 circulating through the second temperature adjustment circuit 62. In the present embodiment, the second temperature sensor 62a is provided in the pressure feed flow path 620a between the radiator 622 and the branching portion 624, and detects the temperature of the second temperature adjustment medium TCM2 stored in the storage tank 623. The second temperature sensor 62a outputs a detection value of the temperature of the second temperature adjustment medium TCM2 discharged from the radiator 622 to the control device ECU.

In the first temperature adjustment circuit 61, the temperature of the first temperature adjustment medium TCM1 stored in the storage unit 612 after cooling the electric motor 20, the power generator 30, and the transmission device 40 is about 100 [° C.]. Therefore, the first temperature adjustment medium TCM1 of about 100 [° C.] is supplied to the heat exchanger 63.

Meanwhile, in the second temperature adjustment circuit 62, a temperature of the second temperature adjustment medium TCM2 cooled by the radiator 622 is about 40 [° C.].

Since the second temperature adjustment medium TCM2 supplied to the heat exchanger 63 does not pass through the electric power conversion device 50 which is a temperature-adjusted device, the second temperature adjustment medium TCM2 of about 40 [° C.] is supplied to the heat exchanger 63.

The heat exchanger 63 performs heat exchange between the first temperature adjustment medium TCM1 of about 100 [° C.] and the second temperature adjustment medium TCM2 of about 40 [° C.] which are supplied to the heat exchanger 63. Then, the first temperature adjustment medium TCM1 of about 80 [° C.] is discharged from the heat exchanger 63 to a downstream side of the first branch flow path 610b1 of the first temperature adjustment circuit 61, and the second temperature adjustment medium TCM2 of about 70 [° C.] is discharged from the heat exchanger 63 to a downstream side of the second branch flow path 620b2 of the second temperature adjustment circuit 62.

In this way, since the first temperature adjustment medium TCM1 is cooled in the heat exchanger 63, the temperature adjustment circuit 60 can cool the first temperature adjustment medium TCM1 without providing a radiator for cooling the first temperature adjustment medium TCM1. Therefore, since the temperature adjustment circuit 60 can cool the first temperature adjustment medium TCM1 flowing through the first temperature adjustment circuit 61 and the second temperature adjustment medium TCM2 flowing through the second temperature adjustment circuit 62 by one radiator 622, the temperature adjustment circuit 60 can be miniaturized.

The control device ECU controls the internal combustion engine ICE, the electric power conversion device 50, the second pump 621, and the valve device 626. A rotational speed sensor 621a which detects a rotational speed of the second pump 621 is attached to the second pump 621. The rotational speed sensor 621a outputs a detection value of the rotational speed of the second pump 621 to the control device ECU.

Returning to FIG. 1, when the first temperature adjustment medium TCM1 is ATF, a viscosity of the first temperature adjustment medium TCM1 is increased as the temperature of the first temperature adjustment medium TCM1 is decreased. Since the first temperature adjustment medium TCM1 flows through the electric motor 20 and the power generator 30, a friction loss generated in the electric motor 20 and the power generator 30 is increased, and output efficiencies of the electric motor 20 and the power generator 30 is decreased when the viscosity is increased. Therefore, when the electric motor 20 and the power generator 30 are not at a high temperature at the time of starting the electric motor 20 and the power generator 30 or the like, and the temperature of the first temperature adjustment medium TCM1 is equal to or lower than a predetermined temperature, the first temperature adjustment medium TCM1 does not need to be cooled and it is preferable that the first temperature adjustment medium TCM1 is not cooled.

When the detection value of the temperature of the first temperature adjustment medium TCM1 output from the first temperature sensor 61a is equal to or lower than the predetermined temperature, the control device ECU fully closes the valve device 626 and controls the valve device 626 so as to block the second temperature adjustment medium TCM2 from flowing through the second branch flow path 620b2.

When the second temperature adjustment medium TCM2 is blocked from flowing through the second branch flow path 620b2, the second temperature adjustment medium TCM2 is not supplied to the heat exchanger 63, and therefore, the heat exchange is not performed between the first temperature adjustment medium TCM1 and the second temperature adjustment medium TCM2, and the first temperature adjustment medium TCM1 is not cooled. Therefore, when the first temperature adjustment medium TCM1 does not need to be cooled, the first temperature adjustment medium TCM1 can be prevented from being cooled in the heat exchanger 63. As a result, it is possible to prevent an increase in friction loss generated in the electric motor 20 and the power generator 30.

As described above, the second temperature adjustment circuit 62 which adjusts the temperature of the electric power conversion device 50 includes the first branch flow path 620b1 of the second temperature adjustment medium TCM2 which bypasses the heat exchanger 63, the second branch flow path 620b2 of the second temperature adjustment medium TCM2 which passes through the heat exchanger 63, and the valve device 626 (flow rate adjustment valve) which adjusts the flow rate of the second temperature adjustment medium TCM2 to the first branch flow path 620b1.

Accordingly, since the inflow of the second temperature adjustment medium TCM2 into the heat exchanger 63 can be adjusted, it is possible to prevent temperature decrease of the first temperature adjustment medium TCM1 due to heat exchange between the first temperature adjustment medium TCM1 and the second temperature adjustment medium TCM2, which are used for temperature adjustment of the electric motor 20 and the power generator 30 (rotary electric machine), and to prevent friction loss generated in the electric motor 20 and the power generator 30. Therefore, it is possible to prevent a decrease in the output efficiency of the electric motor 20 and the power generator 30.

For example, when the temperature detected by the first temperature sensor 61a which detects the temperature of the first temperature adjustment medium TCM1 is equal to or less than a threshold value (predetermined value), the control device ECU controls the valve device 626 such that the flow rate of the second temperature adjustment medium TCM2 to the second branch flow path 620b2 is smaller than a flow rate when the temperature detected by the first temperature sensor 61a exceeds the threshold value.

The control of the valve device 626 such that the flow rate of the second temperature adjustment medium TCM2 to the second branch flow path 620b2 is small also includes fully closing the valve device 626 such that the second temperature adjustment medium TCM2 does not flow to the second branch flow path 620b2. For example, the control device ECU fully closes the valve device 626 when the temperature detected by the first temperature sensor 61a is equal to or lower than the threshold value, and fully opens the valve device 626 when the temperature detected by the first temperature sensor 61a exceeds the threshold value.

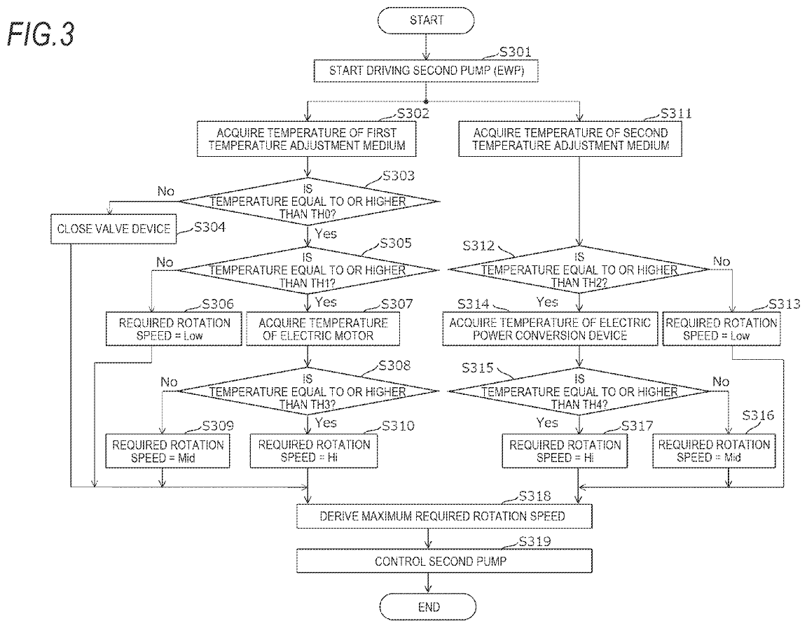

Accordingly, when the temperature of the first temperature adjustment medium TCM1 is equal to or lower than the threshold value, the inflow of the second temperature adjustment medium TCM2 into the heat exchanger 63 is limited, the heat exchange between the first temperature adjustment medium TCM1 and the second temperature adjustment medium TCM2 is prevented, and the temperature decrease of the first temperature adjustment medium TCM1 can be prevented. The threshold value is, for example, a threshold value TH0 to be described later. The control of the valve device 626 based on the comparison between the temperature of the first temperature adjustment medium TCM1 and the threshold value TH0 will be described later with reference to FIG. 3.

When the temperature detected by the third temperature sensor 20a which detects the temperature of the electric motor 20 is equal to or lower than the threshold value, the control device ECU may control the valve device 626 such that the flow rate of the second temperature adjustment medium TCM2 to the second branch flow path 620b2 is smaller than the flow rate when the temperature detected by the third temperature sensor 20a exceeds the threshold value.

Accordingly, by limiting the inflow of the second temperature adjustment medium into the heat exchanger when the temperature of the electric motor 20 is equal to or lower than the threshold value, it is possible to prevent the heat exchange between the first temperature adjustment medium TCM1 and the second temperature adjustment medium TCM2 and prevent the temperature decrease of the first temperature adjustment medium TCM1 in a state where cooling of the electric motor 20 is not required much.

The third temperature sensor 20a may be a sensor which detects the temperature of the power generator 30 instead of the electric motor 20. Also in this case, when the temperature detected by the third temperature sensor 20a which detects the temperature of the power generator 30 is equal to or lower than the threshold value, the control device ECU may control the valve device 626 such that the flow rate of the second temperature adjustment medium TCM2 to the second branch flow path 620b2 is smaller than the flow rate when the temperature detected by the third temperature sensor 20a exceeds the threshold value.

Accordingly, by limiting the inflow of the second temperature adjustment medium into the heat exchanger when the temperature of the power generator 30 is equal to or lower than the threshold value, it is possible to prevent the heat exchange between the first temperature adjustment medium TCM1 and the second temperature adjustment medium TCM2 and prevent the temperature decrease of the first temperature adjustment medium TCM1 in a state where cooling of the power generator 30 is not required much.

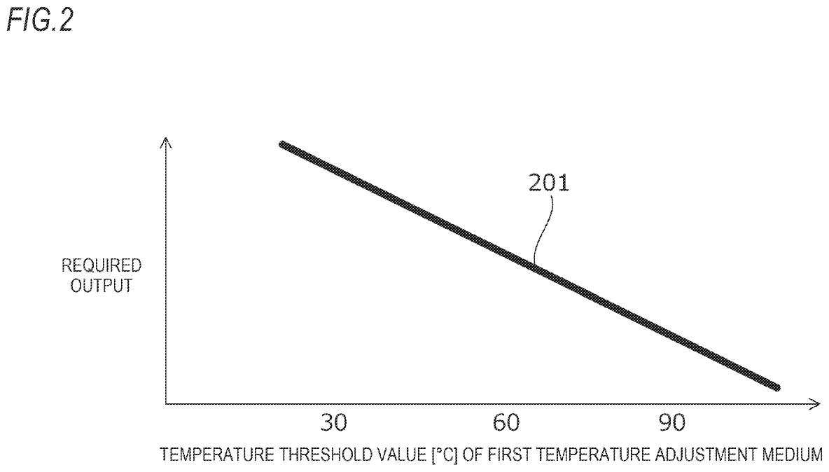

The control of the valve device 626 in accordance with the increase in the required output of the electric motor 20 will be described with reference to FIG. 2. A temperature threshold characteristic 201 in FIG. 2 is, for example, information stored in a memory accessible by the control device ECU, and indicates the temperature threshold value (predetermined value) for controlling the valve device 626 according to the required output of the electric motor 20 in the vehicle V. The required output is an output required for the electric motor 20, and is, for example, information based on an accelerator pedal opening degree of the vehicle V, a vehicle speed of the vehicle V, or the like.

In the temperature threshold characteristic 201, the higher the required output of the electric motor 20 is, the lower the temperature threshold value is. The control device ECU may acquire a threshold value corresponding to the required output of the electric motor 20 in accordance with the temperature threshold value characteristic 201, and may control the valve device 626 based on the temperature using the acquired threshold value.

That is, as described above, the control device ECU compares the temperature detected by the first temperature sensor 61a or the third temperature sensor 20a with the threshold value. The control device ECU controls the valve device 626 such that when the temperature is equal to or lower than the threshold value, the flow rate of the second temperature adjustment medium TCM2 to the second branch flow path 620b2 is smaller than the flow rate when the temperature exceeds the threshold value. Then, the control device ECU decreases the threshold value in accordance with the increase in the required output of the electric motor 20.

In this way, the control device ECU may decrease the temperature threshold value (predetermined value) for controlling the valve device 626 in accordance with the increase in the required output of the electric motor 20. For example, in a situation where the temperatures of the first temperature adjustment medium TCM1 and the electric motor 20 are low and the valve device 626 is closed and the heat exchange between the first temperature adjustment medium TCM1 and the second temperature adjustment medium TCM2 is not performed, the threshold value is decreased when the required output of the electric motor 20 is increased. Accordingly, before the temperature of the electric motor 20 is actually raised, the valve device 626 is opened to start the heat exchange between the first temperature adjustment medium TCM1 and the second temperature adjustment medium TCM2, and the first temperature adjustment medium TCM1 can be cooled, so that the temperature raising of the electric motor 20 can be prevented.

The control device ECU may adjust a temperature threshold value (predetermined value) for controlling the valve device 626 based on a traveling mode of the vehicle V. The traveling mode is a traveling mode of the vehicle V in which the presence or absence of use of the electric motor 20 and the form thereof are different.

For example, when the traveling mode of the vehicle V is a traction traveling mode in which a high load is applied to the electric motor 20, the control device ECU sets the temperature threshold value for controlling the valve device 626 to be relatively low. As a result, it is possible to prevent the temperature raising of the electric motor 20 by advancing a timing at which the valve device 626 is opened to cool the first temperature adjustment medium TCM1.

When the traveling mode of the vehicle V is a lock-up traveling mode (engine direct connection mode) in which the load of the electric motor 20 is low, the control device ECU sets the temperature threshold value for controlling the valve device 626 to be relatively high. Accordingly, by delaying the timing at which the valve device 626 is opened to cool the first temperature adjustment medium TCM1, it is possible to prevent the temperature decrease of the first temperature adjustment medium TCM1.

In this way, the temperature of the electric motor 20 can be appropriately adjusted by controlling the valve device 626 to change the timing of cooling the first temperature adjustment medium TCM1 based on the traveling mode of the vehicle V.

The control device ECU may control the rotation speed of the second pump 621 based on the temperature detected by each temperature sensor. The control of the rotational speed of the second pump 621 by the control device ECU will be described with reference to FIG. 3. For example, when an ignition power source of the vehicle V is turned on, the control device ECU executes the process illustrated in FIG. 3. As an initial state, it is assumed that the valve device 626 is fully opened.

First, the control device ECU starts driving the second pump 621 (step S301). Specifically, the control device ECU starts driving the second pump 621 by inputting a drive signal of a predetermined duty ratio to the second pump 621.

The second pump 621 operates at a rotation speed corresponding to the duty ratio of the drive signal input from the control device ECU, thereby pressure-feeding the second temperature adjustment medium TCM2. Here, it is assumed that there are three rotational speeds of Low, Mid, and Hi as the required rotational speed for the second pump 621. Low is the lowest rotational speed, and Hi is the highest rotational speed.

Next, the control device ECU executes the processes in steps S302 to S310 and the processes in steps S311 to S317. These processes may be executed in parallel or sequentially.

In step S302, the control device ECU acquires the temperature of the first temperature adjustment medium TCM1 detected by the first temperature sensor 61a (step S302). Next, the control device ECU determines whether the temperature acquired in step S302 is equal to or higher than the threshold value TH0 (step S303). The threshold value TH0 is a minimum temperature of the first temperature adjustment medium TCM1 to such an extent that friction loss generated in the electric motor 20 and the power generator 30 does not cause a problem, and may be, for example, 65 [° C.].

In step S303, when the temperature acquired in step S302 is not equal to or higher than the threshold value TH0 (step S303: No), the control device ECU closes the valve device 626 (step S304), and proceeds to step S318. In this case, a temperature raising mode is set in which the heat exchange between the first temperature adjustment medium TCM1 and the second temperature adjustment medium TCM2 in the heat exchanger 63 is not performed. In the temperature raising mode, since the first temperature adjustment medium TCM1 is not cooled by the heat exchange with the second temperature adjustment medium TCM2, the temperature of the first temperature adjustment medium TCM1 is raised, and as a result, the temperature of the electric motor 20, the power generator 30, and the transmission device 40 are also raised.

When the temperature acquired in step S302 is equal to or higher than the threshold value TH0 (step S303: Yes), the control device ECU determines whether the temperature acquired in step S302 is equal to or higher than a first threshold value TH1 (step S305). The first threshold value TH1 is a value higher than the threshold value TH0, and may be, for example, 70 [° C.].

In step S305, when the temperature acquired in step S302 is not equal to or higher than the first threshold value TH1 (step S305: No), the control device ECU sets the required rotation speed of the second pump 621 to Low (step S306), and proceeds to step S318.

In step S305, when the temperature acquired in step S302 is equal to or higher than the first threshold value TH1 (step S305: Yes), the control device ECU acquires the temperature of the electric motor 20 detected by the third temperature sensor 20a (step S307).

Next, the control device ECU determines whether the temperature acquired in step S307 is equal to or higher than a third threshold value TH3 (step S308). The third threshold value TH3 is a value higher than the first threshold value TH1, and may be, for example, 80 [° C.].

In step S308, when the acquired temperature is not equal to or higher than the third threshold value TH3 (step S308: No), the control device ECU sets the requested rotation speed of the second pump 621 to Mid (step S309), and proceeds to step S318. When the acquired temperature is equal to or higher than the third threshold value TH3 (step S308: Yes), the control device ECU sets the required rotation speed of the second pump 621 to Hi (step S310), and proceeds to step S318.

In step S311, the control device ECU acquires the temperature of the second temperature adjustment medium TCM2 detected by the second temperature sensor 62a (step S311). Next, the control device ECU determines whether the temperature acquired in step S311 is equal to or higher than a second threshold TH2 (step S312). The second threshold value TH2 is, for example, the same value as the first threshold value TH1 for comparison with the temperature of the first temperature adjustment medium TCM1, and may be, for example, 70 [° C.]. However, since the temperature of the second temperature adjustment medium TCM2 is normally lower than that of the first temperature adjustment medium TCM1, the second threshold value TH2 may be set to a value lower than the first threshold value TH1.

In step S312, when the temperature acquired in step S311 is not equal to or higher than the second threshold value TH2 (step S312: No), the control device ECU sets the required rotation speed of the second pump 621 to Low (step S313), and proceeds to step S318.

In step S312, when the temperature acquired in step S311 is equal to or higher than the second threshold TH2 (step S312: Yes), the control device ECU acquires the temperature of the electric power conversion device 50 detected by the fourth temperature sensor 50a (step S314).

Next, the control device ECU determines whether the temperature acquired in step S314 is equal to or higher than a fourth threshold value TH4 (step S315). The fourth threshold value TH4 is, for example, the same value as the third threshold value TH3 for comparison with the temperature of the electric motor 20, and may be, for example, 80 [° C.]. However, since the temperature of the electric power conversion device 50 is normally lower than that of the electric motor 20, the fourth threshold value TH4 may be set to a value lower than the third threshold value TH3.

In step S315, when the acquired temperature is not equal to or higher than the fourth threshold value TH4 (step S315: No), the control device ECU sets the requested rotation speed of the second pump 621 to Mid (step S316), and proceeds to step S318. When the acquired temperature is equal to or higher than the fourth threshold value TH4 (step S315: Yes), the control device ECU sets the required rotation speed of the second pump 621 to Hi (step S317), and proceeds to step S318.

In step S318, the control device ECU derives the maximum required rotation speed among the required rotation speed of the second pump 621 set in any one of steps S306, S309, and S310 and the required rotation speed of the second pump 621 set in any one of steps S313. S316, and S317 as the rotation speed to be set in the second pump 621 (step S318). However, when the valve device 626 is closed in step S304, the control device ECU derives the required rotation speed of the second pump 621 set in any one of steps S313, S316, and S317 as the rotation speed to be set in the second pump 621.

Next, the control device ECU controls the second pump 621 so as to operate at the rotation speed derived in step S318 (step S319), and ends the series of processes. Specifically, the control device ECU generates a drive signal in which the duty ratio is adjusted such that the second pump 621 operates at the rotation speed derived in step S318, and inputs the generated drive signal to the second pump 621.

The control device ECU may repeatedly execute the process illustrated in FIG. 3. In this case, the control device ECU omits step S301 in the second and subsequent processes. In this case, the control device ECU performs control to open (for example, fully open) the valve device 626 when it is determined in step S303 that the temperature of the first temperature adjustment medium TCM1 is equal to or higher than the threshold value TH0 and the valve device 626 is in a closed state.

In this way, the control device ECU controls the rotation speed of the second pump 621 based on the first temperature detected by the first temperature sensor 61a which detects the temperature of the first temperature adjustment medium TCM1 and the second temperature detected by the second temperature sensor 62a which detects the temperature of the second temperature adjustment medium TCM2. Accordingly, it is possible to perform cooling when the temperature of the first temperature adjustment medium TCM1 or the second temperature adjustment medium TCM2 is high while preventing the power consumption of the second pump 621.

Specifically, in a case where the first temperature is equal to or higher than the first threshold value TH1 or the second temperature is equal to or higher than the second threshold value TH2 (including a case where the first temperature is equal to or higher than the first threshold value TH1 and the second temperature is equal to or higher than the second threshold value TH2), the control device ECU controls the rotational speed of the second pump 621 to be higher (to be Mid or Hi) than the rotational speed in a case where the first temperature is lower than the first threshold value TH1 and the second temperature is lower than the second threshold value TH2. Thus, when the temperature of at least one of the first temperature adjustment medium TCM1 and the second temperature adjustment medium TCM2 is high, the first temperature adjustment medium TCM1 and the second temperature adjustment medium TCM2 can be cooled.

The control device ECU may control the rotation speed of the second pump 621 based on, in addition to the first temperature and the second temperature, a third temperature detected by the third temperature sensor 20a which detects the temperature of the electric motor 20 or a fourth temperature detected by the fourth temperature sensor 50a which detects the temperature of the electric power conversion device 50.

Accordingly, for example, even when the first temperature of the first temperature adjustment medium TCM1 is equal to or higher than the first threshold value TH1, the requested rotation speed of the second pump 621 is set to Mid lower than Hi, and the power consumption of the second pump 621 can be prevented as long as the third temperature of the electric motor 20 to be cooled by the first temperature adjustment medium TCM1 is lower than the third threshold value TH3. Further, even when the second temperature of the second temperature adjustment medium TCM2 is equal to or higher than the second threshold value TH2, the requested rotation speed of the second pump 621 is set to Mid lower than Hi, and the power consumption of the second pump 621 can be prevented as long as the fourth temperature of the electric power conversion device 50 to be cooled by the second temperature adjustment medium TCM2 is lower than the fourth threshold value TH4.

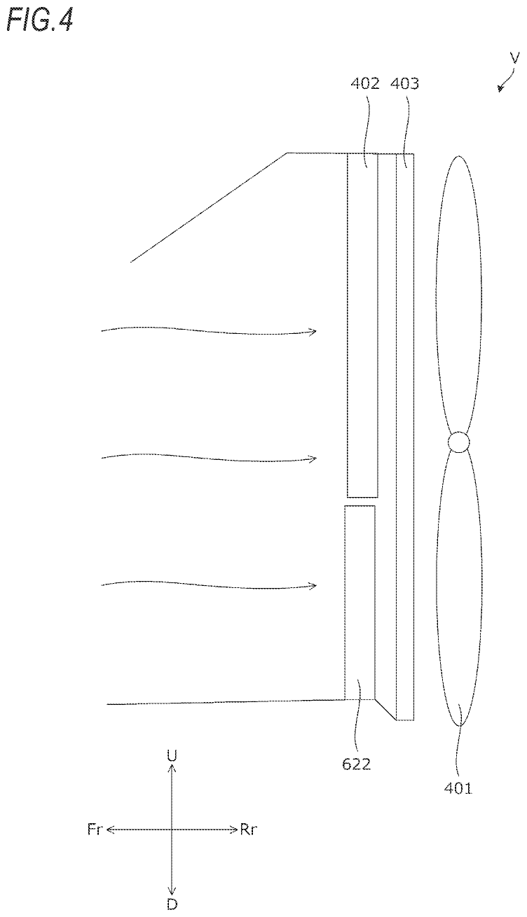

As illustrated in FIG. 4, a fan 401 is provided in a front portion of the vehicle V behind the radiator 622. The fan 401 blows air from the front side (Fr) to the rear side (Rr) of the vehicle V to introduce outside air into the radiator 622.

An air conditioner condenser 402 is a condenser of an air conditioner of the vehicle V, and is located, for example, in front of the fan 401 and above the radiator 622. A first radiator 403 is a radiator for cooling the internal combustion engine ICE, and is located, for example, in front of the fan 401 and behind the radiator 622.

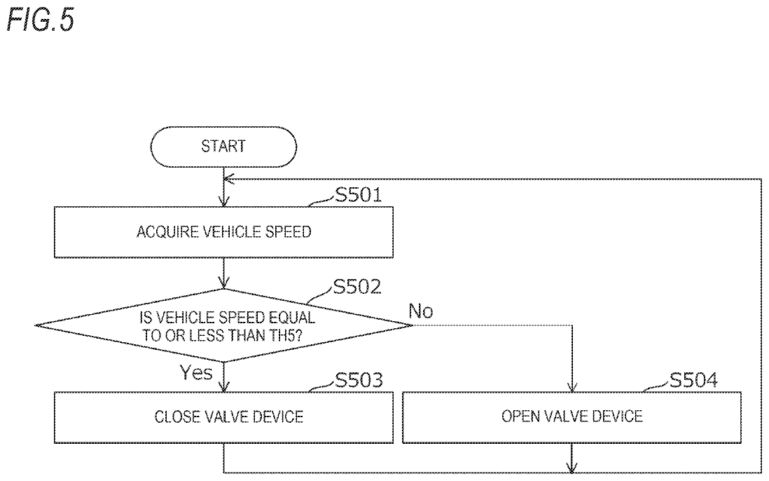

The control of the valve device 626 based on the vehicle speed will be described with reference to FIG. 5. First, the control device ECU acquires the vehicle speed of the vehicle V detected by a vehicle speed sensor provided in the vehicle V (step S501). Next, the control device ECU determines whether the vehicle speed acquired in step S501 is equal to or less than a threshold value TH5 (step S502). The threshold value TH5 may be, for example, 10 km/hour.

In step S502, when the acquired vehicle speed is equal to or less than the threshold value TH5 (step S502: Yes), the control device ECU closes the valve device 626 (step S503), and returns to step S501. In this case, the heat exchange is not performed between the first temperature adjustment medium TCM1 and the second temperature adjustment medium TCM2 in the heat exchanger 63. Therefore, it is possible to prevent the heat of the electric motor 20 and the power generator 30 from being transferred to the radiator 622.

In step S502, when the acquired vehicle speed is not equal to or less than the threshold value TH5 (step S502: No), the control device ECU opens the valve device 626 (step S504), and returns to step S501. In this case, the heat exchange is performed between the first temperature adjustment medium TCM1 and the second temperature adjustment medium TCM2 in the heat exchanger 63. Therefore, the heat of the electric motor 20 and the power generator 30 is transferred to the radiator 622, and the electric motor 20 and the power generator 30 can be cooled.

As described above, the control device ECU prevents the heat exchange between the first temperature adjustment medium TCM1 and the second temperature adjustment medium TCM2 and prevents heat of the electric motor 20 and the power generator 30 (rotary electric machine) from being transferred to the radiator 622 (first radiator) while the vehicle V is stopped or running at a low speed, thereby preventing temperature raising of the outside air due to temperature exchange between the radiator 622 and the outside air and preventing the heat exchange in other heat exchangers such as the air conditioner condenser 402 and the first radiator 403 (second radiator) from being hindered.

Since the electric power conversion device 50 is disposed in the first branch flow path 620b1, the electric power conversion device 50 and the heat exchanger 63 are arranged in parallel. Accordingly, it is possible to reduce the resistance of the second temperature adjustment circuit 62 when the valve device 626 is opened to cool the electric motor 20, and it is possible to use a low output pump as the second pump 621.

Although one embodiment of the present invention has been described above with reference to the accompanying drawings, it is needless to say that the present invention is not limited to such an embodiment. It is apparent to those skilled in the art that various changes and modifications can be conceived within the scope of the claims, and it is also understood that the various changes and modifications belong to the technical scope of the present invention. The components in the embodiments described above may be combined freely within a range not departing from the spirit of the invention.

For example, although the configuration in which the vehicle V includes the internal combustion engine ICE has been described, the vehicle V may be an electric vehicle which does not include the internal combustion engine ICE.

In addition, although the configuration in which the third temperature sensor 20a is provided in the electric motor 20 and the temperature of the electric motor 20 is measured by the third temperature sensor 20a has been described, a configuration in which the third temperature sensor 20a is provided in the power generator 30 and the temperature of the power generator 30 is measured by the third temperature sensor 20a may be adopted.

Although the configuration in which the electric power conversion device 50 and the heat exchanger 63 are arranged in parallel has been described, the electric power conversion device 50 and the heat exchanger 63 may be arranged in series. For example, the electric power conversion device 50 may be arranged between the radiator 622 and the branching portion 624.

In the present specification, at least the following matters are described. In the parentheses, the corresponding constituent elements and the like in the above-described embodiment are illustrated as an example, and the present invention is not limited thereto.

(1) A vehicle temperature adjustment system (vehicle temperature adjustment system 10) including:

a first temperature adjustment circuit (first temperature adjustment circuit 61) which is configured to adjust a temperature of a rotary electric machine (electric motor 20, power generator 30) and in which a first pump (first pump 611) is provided:

a second temperature adjustment circuit (second temperature adjustment circuit 62) which is configured to adjust a temperature of a electric power conversion device (electric power conversion device 50) and in which a second pump (second pump 621) is provided; and

a heat exchanger (heat exchanger 63) configured to perform heat exchange between a first temperature adjustment medium (first temperature adjustment medium TCM1) circulating through the first temperature adjustment circuit and a second temperature adjustment medium (second temperature adjustment medium TCM2) circulating through the second temperature adjustment circuit, in which:

the second temperature adjustment circuit includes.
a first radiator (first radiator 403) configured to perform heat exchange between the second temperature adjustment medium and outside air;
a first branch flow path (first branch flow path 620b1) of the second temperature adjustment medium bypassing the heat exchanger;
a second branch flow path (second branch flow path 620b2) of the second temperature adjustment medium passing through the heat exchanger; and
a flow rate adjustment valve (valve device 626) configured to adjust a flow rate of the second temperature adjustment medium to the second branch flow path.

According to (1), since the second temperature adjustment circuit which adjusts the temperature of the electric power conversion device includes the first branch flow path of the second temperature adjustment medium bypassing the heat exchanger, the second branch flow path of the second temperature adjustment medium passing through the heat exchanger, and the flow rate adjustment valve which adjusts the flow rate of the second temperature adjustment medium to the second branch flow path, it is possible to limit the inflow of the second temperature adjustment medium to the heat exchanger, and thus it is possible to prevent the temperature decrease of the first temperature adjustment medium due to the heat exchange between the first temperature adjustment medium used for the temperature adjustment of the rotary electric machine such as the electric motor and the second temperature adjustment medium, and to prevent the friction loss due to the first temperature adjustment medium.

(2) The vehicle temperature adjustment system according to (1), in which: the first temperature adjustment circuit includes a first temperature sensor (first temperature sensor) which is configured to detect a temperature of the first temperature adjustment medium; and

a control device (control device ECU) configured to control the flow rate adjustment valve such that when the temperature detected by the first temperature sensor is equal to or lower than a predetermined value (TH0), the flow rate of the second temperature adjustment medium to the second branch flow path is smaller than a flow rate when the temperature detected by the first temperature sensor exceeds the predetermined value is provided.

According to (2), by limiting the inflow of the second temperature adjustment medium into the heat exchanger when the temperature of the first temperature adjustment medium is equal to or lower than the predetermined value, it is possible to prevent the heat exchange between the first temperature adjustment medium and the second temperature adjustment medium and to prevent the temperature decrease of the first temperature adjustment medium.

(3) The vehicle temperature adjustment system according to (1) or (2), in which:

the first temperature adjustment circuit includes a third temperature sensor (third temperature sensor 20a) configured to detect a temperature of the rotary electric machine; and

a control device configured to control the flow rate adjustment valve such that when the temperature detected by the third temperature sensor is equal to or lower than a predetermined value, a flow rate of the second temperature adjustment medium to the second branch flow path is smaller than a flow rate when the temperature detected by the third temperature sensor exceeds the predetermined value is provided.

According to (3), by limiting the inflow of the second temperature adjustment medium into the heat exchanger when the temperature of the rotary electric machine is equal to or lower than the predetermined value, it is possible to prevent the heat exchange between the first temperature adjustment medium and the second temperature adjustment medium, and prevent the temperature decrease of the first temperature adjustment medium in a state where cooling of the rotary electric machine is not required so much.

(4) The vehicle temperature adjustment system according to (2) or (3), in which:

the rotary electric machine includes an electric motor (electric motor 20); and

the control device is configured to decrease the predetermined value in accordance with an increase in a required output of the electric motor.

According to (4), by decreasing the reference temperature for limiting the inflow of the second temperature adjustment medium into the heat exchanger in accordance with the increase in the required output of the electric motor, the heat exchange between the first temperature adjustment medium and the second temperature adjustment medium can be started and the first temperature adjustment medium can be cooled before the temperature of the electric motor is actually raised, so that the temperature raising of the electric motor can be prevented.

(5) The vehicle temperature adjustment system according to any one of (2) to (4), which is mounted on an electric vehicle (vehicle V) which travels using the rotary electric machine, in which:

the control device is configured to adjust the predetermined value based on a traveling mode of the electric vehicle.

According to (5), the temperature of the rotary electric machine can be appropriately adjusted by changing the reference temperature for limiting the inflow of the second temperature adjustment medium into the heat exchanger based on the traveling mode of the electric vehicle, thereby changing the timing for cooling the first temperature adjustment medium TCM1 by controlling the flow rate adjustment valve.

(6) The vehicle temperature adjustment system according to any one of (1) to (5), in which:

the second pump is an electric pump;

the first temperature adjustment circuit includes a first temperature sensor (first temperature sensor 61a) configured to detect a temperature of the first temperature adjustment medium:

the second temperature adjustment circuit includes a second temperature sensor (second temperature sensor 62a) configured to detect a temperature of the second temperature adjustment medium; and

a control device configured to control a rotation speed of the electric pump based on a first temperature detected by the first temperature sensor and a second temperature detected by the second temperature sensor is provided.

According to (6), by controlling the rotation speed of the electric pump based on the each temperature of the first temperature adjustment medium and the second temperature adjustment medium, it is possible to perform cooling when the temperature of the first temperature adjustment medium or the second temperature adjustment medium is high while preventing the power consumption of the electric pump.

(7) The vehicle temperature adjustment system according to (6), in which: the control device controls the rotational speed of the electric pump to be higher in a case where the first temperature is equal to or higher than a first threshold value or when the second temperature is equal to or higher than a second threshold value than in a case where the first temperature is lower than the first threshold value (first threshold value TH1) and the second temperature is lower than the second threshold value (second threshold value TH2).

According to (7), when the temperature of at least one of the first temperature adjustment medium and the second temperature adjustment medium is high, it is possible to cool the first temperature adjustment medium and the second temperature adjustment medium.

(8) The vehicle temperature adjustment system according to (6) or (7), in which: the first temperature adjustment circuit includes a third temperature sensor (third temperature sensor) configured to detect a temperature of the rotary electric machine; and the control device is configured to control a rotation speed of the electric pump based on the first temperature, the second temperature, and a third temperature detected by the third temperature sensor.

According to (8), even when the temperature of the first temperature adjustment medium is high, the rotation speed of the electric pump is set to be relatively low when the temperature of the rotary electric machine to be cooled by the first temperature adjustment medium is not high, and the power consumption of the electric pump can be prevented.

(9) The vehicle temperature adjustment system according to any one of (6) to (8), in which:

the second temperature adjustment circuit includes a fourth temperature sensor (fourth temperature sensor 50a) configured to detect a temperature of the electric power conversion device; and

the control device is configured to control a rotation speed of the electric pump based on the first temperature, the second temperature, and a fourth temperature detected by the fourth temperature sensor.

According to (9), even when the temperature of the second temperature adjustment medium is high, the rotation speed of the electric pump is set to be relatively low when the temperature of the electric power conversion device to be cooled by the first temperature adjustment medium is not high, and the power consumption of the electric pump can be prevented.

(10) The vehicle temperature adjustment system according to any one of (1) to (9), which is mounted on an electric vehicle which travels using the rotary electric machine, in which:

a control device configured to control the flow rate adjustment valve such that when a vehicle speed of the electric vehicle is equal to or less than a predetermined value, a flow rate of the second temperature adjustment medium to the second branch flow path is smaller than a flow rate when the vehicle speed exceeds the predetermined value is provided.

According to (10), while the electric vehicle is stopped or running at a low speed, the heat exchange between the first temperature adjustment medium and the second temperature adjustment medium is prevented to prevent the heat of the rotary electric machine from being transferred to the first radiator, so that the temperature raising of the outside air due to the temperature exchange between the first radiator and the outside air can be prevented, and the heat exchange in other heat exchangers such as the air conditioner condenser and the second radiator can be prevented from being hindered.

(11) The vehicle temperature adjustment system according to any one of (1) to (10), in which the electric power conversion device is disposed in the first branch flow path.

According to (11), the electric power conversion device and the heat exchanger are in a parallel relationship, so that it is possible to reduce the resistance of the second temperature adjustment circuit when the flow rate adjustment valve is opened to cool the electric motor, and it is possible to use a low output pump as the second pump.

What is claimed is:

1. A vehicle temperature adjustment system, comprising:
a first temperature adjustment circuit which is configured to adjust a temperature of a rotary electric machine and in which a first pump is provided;
a second temperature adjustment circuit which is configured to adjust a temperature of an electric power conversion device and in which a second pump is provided; and
a heat exchanger configured to perform heat exchange between a first temperature adjustment medium circulating through the first temperature adjustment circuit and a second temperature adjustment medium circulating through the second temperature adjustment circuit, wherein:
the second temperature adjustment circuit includes:
a first radiator configured to perform heat exchange between the second temperature adjustment medium and outside air;
a first branch flow path of the second temperature adjustment medium bypassing the heat exchanger;
a second branch flow path of the second temperature adjustment medium passing through the heat exchanger; and
a flow rate adjustment valve configured to adjust a flow rate of the second temperature adjustment medium to the second branch flow path.

2. The vehicle temperature adjustment system according to claim 1, wherein:
the first temperature adjustment circuit includes a first temperature sensor which is configured to detect a temperature of the first temperature adjustment medium; and
a control device configured to control the flow rate adjustment valve such that when the temperature detected by the first temperature sensor is equal to or lower than a predetermined value, the flow rate of the second temperature adjustment medium to the second branch flow path is smaller than a flow rate when the temperature detected by the first temperature sensor exceeds the predetermined value is provided.

3. The vehicle temperature adjustment system according to claim 1, wherein:
the first temperature adjustment circuit includes a third temperature sensor configured to detect a temperature of the rotary electric machine; and
a control device configured to control the flow rate adjustment valve such that when the temperature detected by the third temperature sensor is equal to or lower than a predetermined value, the flow rate of the second temperature adjustment medium to the second branch flow path is smaller than a flow rate when the temperature detected by the third temperature sensor exceeds the predetermined value is provided.

4. The vehicle temperature adjustment system according to claim 2, wherein:
the rotary electric machine includes an electric motor; and
the control device is configured to decrease the predetermined value in accordance with an increase in a required output of the electric motor.

5. The vehicle temperature adjustment system according to claim 2, which is mounted on an electric vehicle which travels using the rotary electric machine, wherein:
the control device is configured to adjust the predetermined value based on a traveling mode of the electric vehicle.

6. The vehicle temperature adjustment system according to claim 1, wherein:
the second pump is an electric pump;
the first temperature adjustment circuit includes a first temperature sensor configured to detect a temperature of the first temperature adjustment medium;
the second temperature adjustment circuit includes a second temperature sensor configured to detect a temperature of the second temperature adjustment medium; and
a control device configured to control a rotation speed of the electric pump based on a first temperature detected by the first temperature sensor and a second temperature detected by the second temperature sensor is provided.

7. The vehicle temperature adjustment system according to claim 6, wherein:
the control device is configured to perform control to increase the rotational speed of the electric pump when the first temperature is equal to or higher than a first threshold value or the second temperature is equal to or higher than a second threshold value, as compared with a case where the first temperature is lower than the first threshold value and the second temperature is lower than the second threshold value.

8. The vehicle temperature adjustment system according to claim 6, wherein:
the first temperature adjustment circuit includes a third temperature sensor configured to detect a temperature of the rotary electric machine; and
the control device is configured to control a rotation speed of the electric pump based on the first temperature, the second temperature, and a third temperature detected by the third temperature sensor.

9. The vehicle temperature adjustment system according to claim 6, wherein:
the second temperature adjustment circuit includes a fourth temperature sensor configured to detect a temperature of the electric power conversion device; and
the control device is configured to control a rotation speed of the electric pump based on the first temperature, the second temperature, and a fourth temperature detected by the fourth temperature sensor.

10. The vehicle temperature adjustment system according to claim 1, which is mounted on the electric vehicle which travels using the rotary electric machine, wherein:
a control device configured to control the flow rate adjustment valve such that when a vehicle speed of the electric vehicle is equal to or less than a predetermined value, a flow rate of the second temperature adjustment medium to the second branch flow path is smaller than a flow rate when the vehicle speed exceeds the predetermined value is provided.

11. The vehicle temperature adjustment system according to claim 1, wherein the electric power conversion device is disposed in the first branch flow path.
